(19) United States
(12) Patent Application Publication
(10) Pub. No.: US 2016/0133841 A1
(43) Pub. Date: May 12, 2016

(54) METHOD OF MANUFACTURING ORGANIC LIGHT EMITTING DIODE DISPLAY

(71) Applicant: Samsung Display Co., Ltd., Yongin-si (KR)

(72) Inventor: Jin Won Sun, Seoul (KR)

(21) Appl. No.: 14/920,746

(22) Filed: Oct. 22, 2015

(30) Foreign Application Priority Data
Nov. 11, 2014 (KR) 10-2014-0156100

(51) Int. Cl. H01L 51/00; H01L 51/50; H01L 27/32; H01L 51/56

(52) U.S. Cl. CPC H01L 51/0026; H01L 51/56; H01L 51/5044; H01L 51/5028; H01L 27/3248; H01L 2227/323

(57) ABSTRACT

A manufacturing method of an organic light emitting diode display is disclosed. In one aspect, the method includes forming a thin film transistor and a first electrode over a substrate and forming a first organic emission layer over the first electrode. The method further includes forming a second organic emission layer over the first organic emission layer, applying heat to the first and second organic emission layers and forming a second electrode over the second organic emission layer.

### CROSS-REFERENCE TO RELATED APPLICATION

This application claims priority to and the benefit of Korean Patent Application No. 10-2014-0156100 filed in the Korean Intellectual Property Office on Nov. 11, 2014, the entire contents of which are incorporated herein by reference.

### BACKGROUND

1. Field

The described technology generally relates to a manufacturing method of an organic light emitting diode display.

2. Description of the Related Technology

Display devices include a liquid crystal display (LCD), a plasma display panel (PDP), an organic light emitting diode (OLED) display, a field effect display (FED), an electrophoretic display, and the like.

Particularly, the OLED device includes two electrodes and an organic emission layer positioned therebetween, and an electron injected from one electrode and a hole injected from the other electrode are coupled with each other in the organic emission layer to generate an exciton, and the exciton emits energy to emit light.

Since the OLED device has a self-luminance characteristic and does not require a separate light source unlike the LCD, thickness and weight thereof may be reduced. Further, since the OLED device has high-grade characteristics such as low power consumption, high luminance, and a high response speed, OLED technology is considered to be a next-generation display.

### SUMMARY OF CERTAIN INVENTIVE ASPECTS

An exemplary embodiment provides a manufacturing method of an OLED display in which adherence of an interface between organic emission layers formed by different processes is improved.

A manufacturing method of an OLED display according to an exemplary embodiment includes: forming a thin film transistor and a first electrode on a substrate; forming a first organic emission layer on the first electrode; forming a second organic emission layer on the first organic emission layer; applying heat to the first and second organic emission layers; and forming a second electrode on the second organic emission layer.

The first and second emission layer may be heated at 90 degrees to 130 degrees.

The first and second emission layer may be heated for 8 minutes to 12 minutes.

The first and second emission layers may be heated by a coil heater.

The first and second emission layers may be heated for 1 minute to 2 minutes.

The first and second emission layers may be heated by an infrared lamp.

Before heating the first and second organic emission layers, a heating unit heating the first and second organic emission layers may be positioned to be separated from an upper surface of the second organic emission layer by a predetermined distance.

The heating unit may be separated from the second organic emission layer by 0.5 mm to 3 mm.

The first organic emission layer may be a blue organic emission layer.

The second organic emission layer may be a red or green organic emission layer.

The first organic emission layer may be formed by a deposition process.

The second organic emission layer may be formed by a thermal transition process.

The method may further include forming a hole auxiliary layer between the first electrode and the first organic emission layer.

The method may further include forming an electron auxiliary layer between the second organic emission layer and the second electrode.

In the step of forming the first and second organic emission layers, an assistance dopant may be added to the first and second organic emission layers.

Another aspect is a method of manufacturing an organic light emitting diode display, comprising: forming a thin film transistor and a first electrode over a substrate; forming a first organic emission layer over the first electrode; forming a second organic emission layer over the first organic emission layer; applying heat to the first and second organic emission layers; and forming a second electrode over the second organic emission layer.

In the above method, the first and second emission layers are heated at about 90 degrees to about 130 degrees. In the above method, the first and second emission layers are heated at about 100 degrees to about 120 degrees. In the above method, the first and second emission layers are heated for about 8 minutes to about 12 minutes. In the above method, the first and second emission layers are heated by a coil heater. In the above method, the first and second emission layers are heated for about 1 minute to about 2 minutes. In the above method, the first and second emission layers are heated by an infrared lamp. In the above method, before heating the first and second organic emission layers, a heating unit heating the first and second organic emission layers is positioned to be separated from an upper surface of the second organic emission layer by a predetermined distance.

In the above method, the heating unit is separated from the second organic emission layer by about 0.5 mm to about 3 mm. In the above method, the first organic emission layer is a blue organic emission layer. In the above method, the second organic emission layer is a red or green organic emission layer. In the above method, the first organic emission layer is formed by a deposition process. In the above method, the second organic emission layer is formed by a thermal transition process. In the above method, a hole auxiliary layer is formed between the first electrode and the first organic emission layer. In the above method, an electron auxiliary layer is formed between the second organic emission layer and the second electrode. In the above method, in forming the first and second organic emission layers, an assistance dopant is added to the first and second organic emission layers.

Another aspect is a method of manufacturing an organic light emitting diode (OLED) display, comprising: providing a substrate; and forming an OLED over the substrate, wherein the forming of the OLED comprises: forming a first electrode over the substrate; forming a first organic emission layer over the first electrode; forming a second organic emission layer over the first organic emission layer; applying heat to the first and second organic emission layers such that the first and second organic emission layers are adhered to each other; and forming a second electrode over the second organic emission layer.

In the above method, the first and second emission layers are heated at about 90 degrees to about 130 degrees. In the above method, the first and second emission layers are heated for about 8 minutes to about 12 minutes by a coil heater. In the above method, the first and second emission layers are heated for about 1 minute to about 2 minutes by an infrared lamp.

According to at least one of the disclosed embodiments, when forming the red or green organic emission layer on the blue organic emission layer, by heating the organic emission layer, adherence between the organic emission layers may be improved.

### BRIEF DESCRIPTION OF THE DRAWINGS

FIG. 1 is a flowchart of a manufacturing method of an OLED display according to an exemplary embodiment.

FIG. 2 is a cross-sectional view of an OLED display manufactured according to a manufacturing method thereof.

FIG. 3 to FIG. 5 are schematic diagrams showing a manufacturing process according to a manufacturing method of an OLED display.

FIG. 6 is an enlarged view of a region A of FIG. 4 before heat is applied to an emission layer.

FIG. 7 is an enlarged view of the region A of FIG. 4 after heat is applied to the emission layer.

### DETAILED DESCRIPTION OF CERTAIN INVENTIVE EMBODIMENTS

An organic emission layer may be formed by positioning a blue organic emission layer on a pixel electrode and a red or green organic emission layer on the blue organic emission layer. However, the blue organic emission layer and the red or green organic emission layer are formed through different processes such that there is problem that the blue organic emission layer and the green or red organic emission layer are weakly adhered to each other.

Hereinafter, exemplary embodiments of the present invention will be described in detail so as to be easily practiced by a person skilled in the art to which the described technology pertains, with reference to the accompanying drawings. As those skilled in the art would realize, the described embodiments may be modified in various different ways, all without departing from the spirit or scope of the described technology. The drawings and description are to be regarded as illustrative in nature and not restrictive. Like reference numerals designate like elements throughout the specification.

In addition, the size and thickness of each configuration shown in the drawings are arbitrarily shown for better understanding and ease of description, but the described technology is not limited thereto.

In the drawings, the thickness of layers, films, panels, regions, etc., may be exaggerated for clarity. In the drawings, for better understanding and ease of description, the thickness of some layers and areas is exaggerated. It will be understood that when an element such as a layer, film, region, or substrate is referred to as being “on” another element; it can be directly on the other element or intervening elements may also be present.

Further, in the specification, an upper part of a target portion indicates an upper part or a lower part of the target portion, and it does not mean that the target portion is always positioned at the upper side based on a gravity direction. In this disclosure, the term “substantially” includes the meanings of completely, almost completely or to any significant degree under some applications and in accordance with those skilled in the art. Moreover, “formed on” can also mean “formed over.” The term “connected” includes an electrical connection.

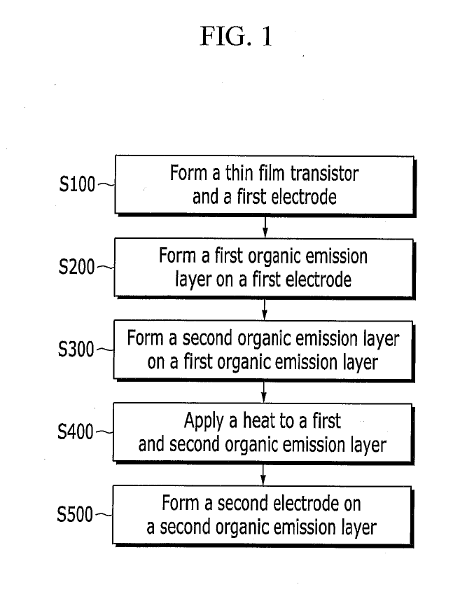

Referring to FIG. 1, the manufacturing method according to the OLED display according to an exemplary embodiment applies heat after forming a second organic emission layer on a first organic emission layer, thereby improving adherence of the first and second organic emission layers.

Firstly, before describing the manufacturing method of the OLED display according to an exemplary embodiment, the OLED display manufactured by the manufacturing method according to an exemplary embodiment will be schematically described.

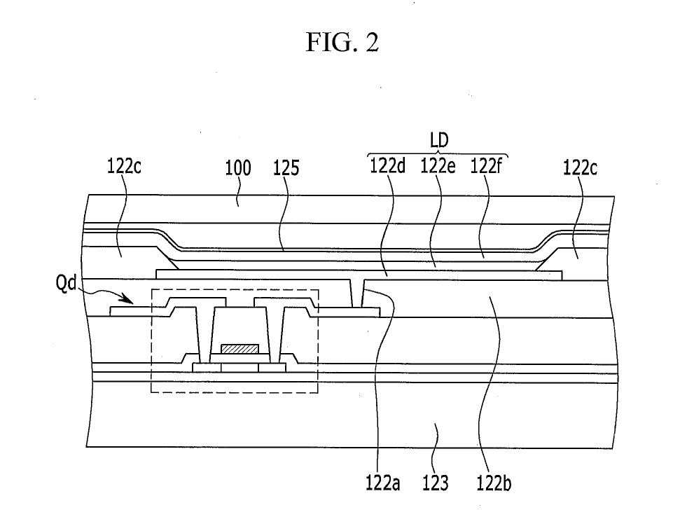

Referring to FIG. 2, a driving transistor Qd is formed over a display substrate 123 that may be made of transparent glass or plastics. The substrate 123 may be formed of an insulating substrate made of glass, quartz, ceramic, or plastic. However, the described technology is not limited thereto, and the substrate 123 may be formed of a metallic substrate made of stainless steel.

A passivation layer 122b made of an inorganic material or an organic material is formed over the driving transistors Qd. When the passivation layer 122b is made of the organic material, the surface thereof may be flat.

The passivation layer 122b has a via hole 122a exposing a portion of the driving transistor Qd.

Also, a first electrode 122d is formed over the passivation layer 122b. The first electrode 122d may include a reflective electrode and a transparent electrode formed thereon. The reflective electrode may be made of a metal having high reflectance, such as silver (Ag) or aluminum (Al), an alloy thereof, or the like, and the transparent electrode may be made of a transparent conductive oxide such as ITO (indium tin oxide) or IZO (indium zinc oxide).

A pixel definition layer 122c covering a circumference of an edge of the first electrode 122d is formed over the passivation layer 122b.

Referring to FIG. 2, an emission layer 122e is formed over the first electrode 122d. Also, a second electrode 122f is formed over the emission layer 122e and the pixel definition layer 122c.

The emission layer 122e may further include organic layers (not shown) for efficiently transferring carriers of holes or electrons to the emission layer in addition to an emission layer (not shown) emitting light in practice. The organic layers may be a hole injection layer (HIL) and a hole transport layer (HTL) positioned between the first electrode 122d and the emission layer, and an electron injection layer (EIL) and an electron transport layer (ETL) positioned between the second electrode 122f and the emission layer.

In this case, the first electrode 122d, the emission layer 122e, and the second electrode 122f form an organic light emitting element LD.

On the other hand, the OLED display has a blue common layer structure in which the blue organic emission layer is formed on the red and green pixel regions as well as the blue pixel region.

Accordingly, a red organic emission layer or a green organic emission layer may be formed over a blue organic emission layer.

A capping layer 125 covering and protecting the second electrode 122f on the second electrode 122f may be formed of an organic layer.

An encapsulation substrate 100 may be positioned to be separated from the capping layer 125. The encapsulation substrate 100 may be formed of a thin film encapsulation shape deposited on the capping layer 125.

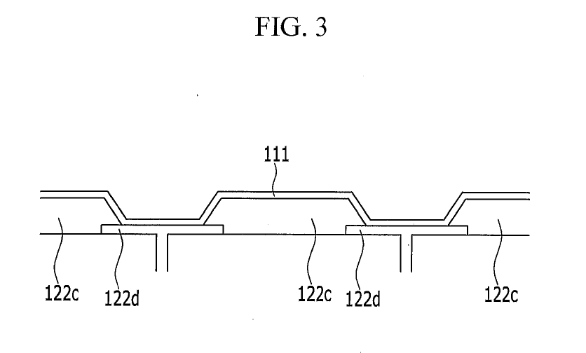

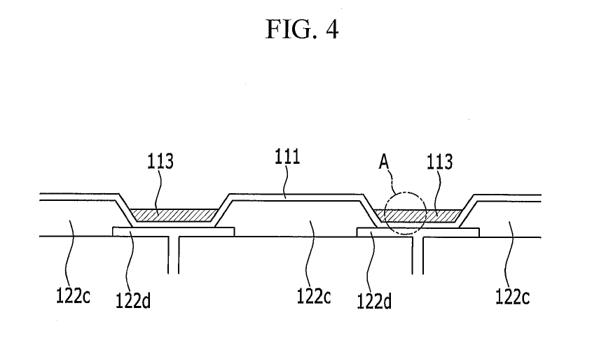

FIG. 3 to FIG. 5 are schematic diagrams showing a manufacturing process according to a manufacturing method of an OLED display, and FIG. 1 is a flowchart of a manufacturing method of an OLED display according to an exemplary embodiment. Hereafter, the manufacturing method of the display device will be described in detail.

First, a thin film transistor and a first electrode 122d are formed over the substrate 123 (S100). Referring to FIG. 2, the driving transistor Qd as the thin film transistor formed over the substrate 123 will be described. However, the described technology is not limited thereto and a switching transistor may be formed.

On the other hand, the first electrode 122d is formed over the thin film transistor. However, as described above, the passivation layer 122b may be formed over the driving transistor Qd of the thin film transistor.

In this case, the passivation layer 122b has the via hole 122a exposing the portion of the driving transistor Qd. Through the via hole 122a, the first electrode 122d and the portion of the driving transistor Qd may contact each other.

Next, a first organic emission layer 111 is formed over the first electrode 122d (S200). In this case, the first organic emission layer 111 may be the blue organic emission layer. The first organic emission layer 111 may also be formed on the red and green pixel regions as well as the blue pixel region. That is, the first organic emission layer 111 of the blue organic emission layer may be commonly formed throughout the red, green, and blue pixels.

On the other hand, the first organic emission layer 111 may be formed by the deposition process. In this case, the deposition process may be realized by an ALD (Atomic Layer Deposition) method, a CVD (Chemical Vapor Deposition) method, or a sputtering method.

As shown in FIG. 3, the first organic emission layer 111 may be formed by commonly depositing the deposition material at the red, green, and blue pixel areas. That is, the first organic emission layer 111 is not formed to be respectively separated in the red, green, and blue pixel areas.

However, before forming the first organic emission layer 111 over the first electrode 122d, a hole auxiliary layer (not shown) may be formed over the first electrode 122d. The hole auxiliary layer may be a hole injection layer or a hole transfer layer.

On the other hand, in the step of forming the first organic emission layer 111, an assistance dopant used in the process forming the second organic emission layer 113 may be added.

For example, the assistance dopant may be a triplet organic material including an ortho-metallic complex such as tris(2-phenylpyridine)iridium (hereinafter referred to as “Ir(ppy)3”), bis(2-T-benzothienyl)-pyridinato-N,C3 Iridium(acetylacetonate) (hereinafter referred to as “btp2Ir(acac)”), bis(2-phenylbenzothiozolato-N,C2)Iridium(acetylacetonate) (referred to as “bt2Ir(acac)”), or bis[4,6-difluorophenyl-pyridinato-N,C2]Iridium(picolinato) (hereinafter referred to as “FIrpic”).

Next, the second organic emission layer 113 is formed over the first organic emission layer 111 (S300). In this case, the second organic emission layer 113 may be the red or green organic emission layer. The second organic emission layer 113 is respectively formed in the red and green pixel regions, differently from the first organic emission layer 111.

That is, the red organic emission layer is formed at the red pixel region, and the green organic emission layer is formed at the green pixel region.

As a result, the blue organic emission layer is commonly formed in the red, green, and blue pixel areas, however the red organic emission layer is only formed in the red pixel region and the green organic emission layer is only formed in the green pixel region.

On the other hand, the second organic emission layer 113 may be formed by a thermal transition process. Here, the thermal transition process may be realized by Laser Induced Thermal Imaging (referred to as “LITI”).

A pattern formation method of the organic emission layer by the LITI requires at least a light source, an acceptor substrate, and a donor substrate. The acceptor substrate is a display substrate on which the organic emission layer is formed and the donor substrate includes a transfer layer composed of a base film, a photothermal conversion layer, and an organic layer.

Patterning of the organic emission layer on the acceptor substrate is performed in such a manner that the photothermal conversion layer absorbs a laser emitted from the light source and converts the laser into thermal energy, and the organic layer forming the transfer layer is transferred onto the acceptor substrate according to the thermal energy.

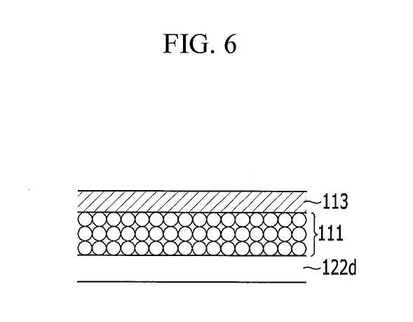

Referring to FIG. 6, the first organic emission layer 111 and the second organic emission layer 113 are formed by different processes such that the adherence of the interface therebetween is weak. As described above, if the interface adherence between the first and second organic emission layers 111 and 113 is weak, luminance non-uniformity in the pixel may be generated.

In some embodiments, to solve this problem, after forming the second organic emission layer 113, a step applying heat to the first and second organic emission layers 111 and 113 is performed (S400).

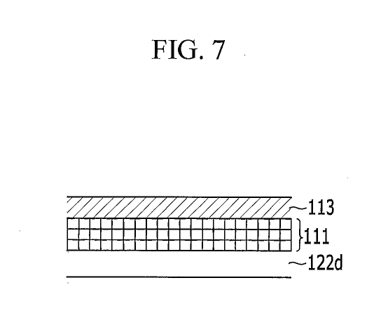

As shown in FIG. 7, by applying the heat to the first and second organic emission layers 111 and 113, the contact area of the first and second organic emission layer 111 and 113 is increased such that the adherence of the first and second organic emission layers 111 and 113 is increased.

For example, referring to FIGS. 6 and 7, while the shape of the deposition material of the first emission layer 111 is changed, the contact area of the first emission layer 111 and the second emission layer 113 is increased.

In this case, the first and second organic emission layers 111 and 113 may be heated at about 90 degrees to about 130 degrees. The first and second organic emission layers 111 and 113 may also be heated at about 100 degrees to about 120 degrees.

The above temperature ranges can provide an optimum balance between the function of the organic emission layer being sufficiently performed and the effect of increasing the contact area of the first and second organic emission layers 111 and 113. However, depending on embodiments, the first and second organic emission layers 111 and 113 can be heated at temperatures less than about 90 degrees or greater than about 130 degrees.

As a device heating the first and second organic emission layers 111 and 113, a coil heater may be used.

When heating the first and second organic emission layers 111 and 113 by the coil heater, the heating may be performed in the temperature range for about 8 minutes to about 12 minutes.

As another heating device, the first and second organic emission layers 111 and 113 may be heated by an infrared lamp.

Differently from the coil heater, when the first and second organic emission layers 111 and 113 are heated by the infrared lamp, the heating may be performed in the temperature range for about 1 minute to about 2 minutes.

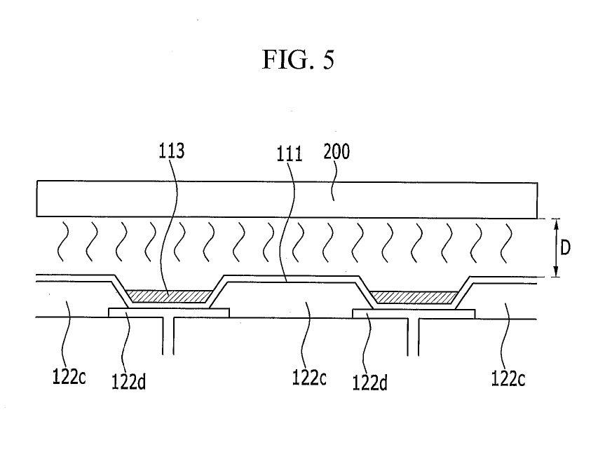

As shown in FIG. 5, before heating the first and second organic emission layers 111 and 113, the heating device 200 is positioned on the second organic emission layer 113.

In this case, an interval D between the heating device 200 and the second organic emission layer 113 may be about 0.5 mm to about 3 mm. The above interval range can provide an optimum balance between obtaining the smoothness of the heat transmission of the heating device 200 and avoiding or minimizing damage to the first and second organic emission layers 111 and 113. However, depending on embodiments, the interval range can be less than about 0.5 mm or greater than about 3 mm.

Next, a second electrode 122f is formed over the second organic emission layer 113 (S500). The second electrode 122f is commonly formed over the entire pixel area,

However, prior to forming the second electrode 122f over the second organic emission layer 113, an electron auxiliary layer (not shown) may be formed over the second organic emission layer 113. The electron auxiliary layer may be an electron injection layer or an electron transfer layer.

The manufacturing method of the OLED display according to an exemplary embodiment applies heat after forming the first and second organic emission layers such that the interface adherence between the organic emission layers may be improved.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing an organic light emitting diode display, comprising:
forming a thin film transistor and a first electrode over a substrate;
forming a first organic emission layer over the first electrode;
forming a second organic emission layer over the first organic emission layer;
applying heat to the first and second organic emission layers; and
forming a second electrode over the second organic emission layer.

2. The method of claim 1, wherein the first and second emission layers are heated at about 90 degrees to about 130 degrees.

3. The method of claim 2, wherein the first and second emission layers are heated at about 100 degrees to about 120 degrees.

4. The method of claim 2, wherein the first and second emission layers are heated for about 8 minutes to about 12 minutes.

5. The method of claim 4, wherein the first and second emission layers are heated by a coil heater.

6. The method of claim 2, wherein the first and second emission layers are heated for about 1 minute to about 2 minutes.

7. The method of claim 6, wherein the first and second emission layers are heated by an infrared lamp.

8. The method of claim 1, wherein, before heating the first and second organic emission layers, a heating unit heating the first and second organic emission layers is positioned to be separated from an upper surface of the second organic emission layer by a predetermined distance.

9. The method of claim 8, wherein the heating unit is separated from the second organic emission layer by about 0.5 mm to about 3 mm.

10. The method of claim 1, wherein the first organic emission layer is a blue organic emission layer.

11. The method of claim 1, wherein the second organic emission layer is a red or green organic emission layer.

12. The method of claim 1, wherein the first organic emission layer is formed by a deposition process.

13. The method of claim 1, wherein the second organic emission layer is formed by a thermal transition process.

14. The method of claim 1, wherein a hole auxiliary layer is formed between the first electrode and the first organic emission layer.

15. The method of claim 1, wherein an electron auxiliary layer is formed between the second organic emission layer and the second electrode.

16. The method of claim 1, wherein, in forming the first and second organic emission layers, an assistance dopant is added to the first and second organic emission layers.

17. A method of manufacturing an organic light emitting diode (OLED) display, comprising:
providing a substrate; and
fanning an OLED over the substrate,
wherein the forming of the OLED comprises:
forming a first electrode over the substrate;
forming a first organic emission layer over the first electrode;
forming a second organic emission layer over the first organic emission layer;
applying heat to the first and second organic emission layers such that the first and second organic emission layers are adhered to each other; and
forming a second electrode over the second organic emission layer.

18. The method of claim 17, wherein the first and second emission layers are heated at about 90 degrees to about 130 degrees.

19. The method of claim 17, wherein the first and second emission layers are heated for about 8 minutes to about 12 minutes by a coil heater.

20. The method of claim 17, wherein the first and second emission layers are heated for about 1 minute to about 2 minutes by an infrared lamp.
